(19) United States
(12) Patent Application Publication
(10) Pub. No.: US 2015/0017797 A1
(43) Pub. Date: Jan. 15, 2015

(54) METHOD OF MANUFACTURING SEMICONDUCTOR DEVICE INCLUDING METAL-CONTAINING CONDUCTIVE LINE

(71) Applicant: SAMSUNG ELECTRONICS CO., LTD., Suwon-si (KR)

(72) Inventors: Jae-hwa PARK, Yongin-si (KR); Man-sug KANG, Suwon-si (KR); Hee-sook PARK, Hwaseong-si (KR); Woong-hee SOHN, Seoul (KR)

(21) Appl. No.: 14/501,492

(22) Filed: Sep. 30, 2014

Related U.S. Application Data
(62) Division of application No. 13/617,323, filed on Sep. 14, 2012.

(30) Foreign Application Priority Data
Sep. 28, 2011 (KR) 10-2011-0098308

(51) Int. Cl. H01L 21/768

(52) U.S. Cl. CPC H01L 21/76877; H01L 21/76802; H01L 21/76846; H01L 21/76864; H01L 21/76876
USPC 438/643

(57) ABSTRACT

A semiconductor device includes: a semiconductor substrate having a trench therein, a metal-containing barrier layer extending along an inner wall of the trench and defining a wiring space in the trench, the wiring space having a first width along a first direction, and a metal-containing conductive line on the metal-containing barrier layer in the wiring space, and including at least one metal grain having a particle diameter of about the first width along the first direction.

### CROSS-REFERENCE TO RELATED APPLICATIONS

This is a divisional application based on pending application Ser. No. 13/617,323, filed Sep. 14, 2012, the entire contents of which is hereby incorporated by reference.

Korean Patent Application No. 10-2011-0098308, filed on Sep. 28, 2011, in the Korean Intellectual Property Office is incorporated by reference herein in its entirety.

### BACKGROUND

1. Field

Embodiments relate to a semiconductor device and a method of fabricating the semiconductor device, and more particularly, to a semiconductor device including metal-containing conductive lines and a method of fabricating the semiconductor device.

2. Description of the Related Art

A semiconductor device may include wires as conductive elements. The wires may be buried in trenches formed in the semiconductor substrate of the semiconductor device. The semiconductor device may have reduced feature sizes as the design rules of the semiconductor device are reduced.

### SUMMARY

Embodiments are directed to a semiconductor device, including: a semiconductor substrate having a trench therein, a metal-containing barrier layer extending along an inner wall of the trench and defining a wiring space in the trench, the wiring space having a first width along a first direction, and a metal-containing conductive line on the metal-containing barrier layer in the wiring space, and including at least one metal grain having a particle diameter of about the first width along the first direction.

The at least one metal grain may include at least one of W, Mo, Pt, or Rh.

The metal-containing conductive line may further include boron (B).

The metal-containing barrier layer may include at least one of Ti, Ta, TiN, TaN, or TiSiN.

The metal-containing conductive line may be formed by: forming at least two metal layers extending along the inner wall of the trench, each of the at least two metal layers having a plurality of smaller metal grains, each of the plurality of smaller metal grains having a particle diameter less than ½ of the first width in the first direction, and increasing the size of at least one of the plurality of smaller metal grains to form the at least one metal grain having a particle diameter of about the first width along the first direction.

Embodiments are also directed to a method including: forming a metal-containing stacked structure on a substrate, the metal-containing stacked structure including: at least two seed layers, and at least one metal layer disposed between the at least two seed layers and including a plurality of metal grains, etching a part of the metal-containing stacked structure to form a metal-containing wiring pattern that includes a remaining part of the metal-containing stacked structure, and annealing the metal-containing wiring pattern.

The at least two seed layers may include boron (B).

The plurality of metal grains may include at least one of W, Mo, Pt, or Rh.

The annealing of the metal-containing wiring pattern may be performed at a temperature of about 800 to about 1000° C.

The annealing of the metal-containing wiring pattern may be performed in a gas atmosphere of at least one of H₂, N₂, or Ar gases.

Embodiments are also directed to a method including: forming a trench in a semiconductor substrate, forming a lower layer extending along an inner wall of the trench and defining a wiring space in the trench, the wiring space having a first width along a first direction, forming a metal-containing stacked structure, the metal-containing stacked structure including: a plurality of seed layers extending along the inner wall of the trench on the lower layer, and at least one metal layer extending along the inner wall of the trench on one of the plurality of seed layers and having a plurality of metal grains, each of the plurality of metal grains having a particle diameter less than ½ of the first width in the first direction, etching a part of the metal-containing stacked structure to form a metal-containing wiring pattern that includes a remaining part of the metal-containing stacked structure, and increasing sizes of at least some of the plurality of metal grains in the metal-containing wiring pattern.

The increasing of the sizes of at least some of the plurality of metal grains may include annealing the metal-containing wiring pattern.

The increasing of the sizes of at least some of the plurality of metal grains may be performed so that the metal-containing wiring pattern includes at least one metal grain having a particle diameter of about the first width along the first direction.

The forming of the metal-containing stacked structure may include: forming a first seed layer including boron (B) on the lower layer, forming a first metal layer by using a chemical vapor deposition (CVD) process, such that the first metal layer extends along the inner wall of the trench on the first seed layer and includes a plurality of metal grains, each of the plurality of metal grains having a particle diameter that is less than ½ of the first width along the first direction, and forming a second seed layer including boron (B) on the first metal layer.

The forming of the metal-containing stacked structure may include: supplying a boron-containing gas onto an exposed surface of the lower layer to form a seed layer, and supplying a metal-containing gas onto the seed layer to form a metal layer.

The metal-containing gas may include at least one of W, Mo, Pt, or Rh.

The first width may be a distance between two parts of the metal-containing barrier layer that are on opposite sides of the inner wall relative to a center of the trench.

In an embodiment, substantially no portion of the at least one metal layer is removed until the etching of a part of the metal-containing stacked structure to form a metal-containing wiring pattern.

### BRIEF DESCRIPTION OF THE DRAWINGS

Features will become apparent to those of skill in the art by describing in detail exemplary embodiments with reference to the attached drawings in which:

FIGS. 1A and 1B illustrate flowcharts of a method of fabricating a semiconductor device according to an embodiment;

FIGS. 2A, 2B, 2C, 2D, and 2E illustrate cross-sectional views of stages in a process of fabricating a semiconductor device according to an embodiment;

FIG. 3A illustrates a cross-sectional view of a plurality of metal grains forming first, second, and third metal layers, which are included in a metal-containing stacked structure shown in FIG. 2D;

FIG. 3B illustrates a cross-sectional view of a plurality of metal grains forming a metal-containing conductive line shown in FIG. 2E;

FIG. 4A illustrates a layout of a semiconductor device according to an embodiment;

FIG. 4B illustrates a cross-sectional view of the semiconductor device taken along line 4B-4B′ of FIG. 4A;

FIG. 4C illustrates a plan view of buried word lines and other components around the word lines shown in FIGS. 4A and 4B;

FIGS. 5A, 5B, 5C, 5D, 5E, 5F, 5G, 5H, 5I, 5J, and 5K illustrate cross-sectional views of stages in a process of fabricating a semiconductor device according to an embodiment;

FIG. 6 illustrates a cross-sectional view showing an expanded view of region A denoted by the dotted lines in FIG. 5E;

FIGS. 7A and 7B illustrate scanning electron microscope (SEM) images for evaluating surface morphologies of bulk W films formed by a method of fabricating a semiconductor device from a metal layer having a relatively large thickness.

FIGS. 7C and 7D illustrate SEM images for evaluating surface morphologies of bulk W films formed by a method of fabricating a semiconductor device from multiple metal layers having relatively small thicknesses;

FIGS. 7E and 7F illustrate SEM images for evaluating the size of W grains before and after annealing of a metal-containing stacked structure;

FIGS. 8A and 8B illustrate SEM images for evaluating the effects of an annealing process on a metal-containing stacked structure formed by a method of fabricating a semiconductor device according to an embodiment;

FIG. 9 illustrates a graph showing a resistance reduction effect according to annealing a metal-containing stacked structure formed in a plurality of trenches in a semiconductor device according to an embodiment;

FIG. 10 illustrates a plan view of a memory module including the semiconductor device according to an embodiment;

FIG. 11 illustrates a schematic diagram of a memory card including the semiconductor device according to an embodiment; and

FIG. 12 illustrates a schematic diagram of a system including the semiconductor device according to an embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

As used herein, the term “and/or” includes any and all combinations of one or more of the associated listed items. Expressions such as “at least one of,” when preceding a list of elements, modify the entire list of elements and do not modify the individual elements of the list.

It will be understood that, although the terms first, second, third, etc., may be used herein to describe various elements, components, regions, layers, and/or sections, these elements, components, regions, layers, and/or sections should not be limited by these terms. These terms are only used to distinguish one element, component, region, layer, or section from another element, component, region, layer, or section. Thus, a first element, component, region, layer, or section discussed below could be termed a second element, component, region, layer, or section without departing from the teachings of the present inventive concept.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Unless specified otherwise, the processing order of a process should not be limited by the order in which the process is described. For example, two processes that are described successively may be performed substantially simultaneously, and may be performed in an opposite order to the description.

Shapes illustrated in the accompanying drawings may be modified according to the fabrication technology and/or tolerances. Therefore, embodiments should not be limited to the shapes illustrated in the drawings, but should include modifications in the shapes that may be caused during the fabrication processes.

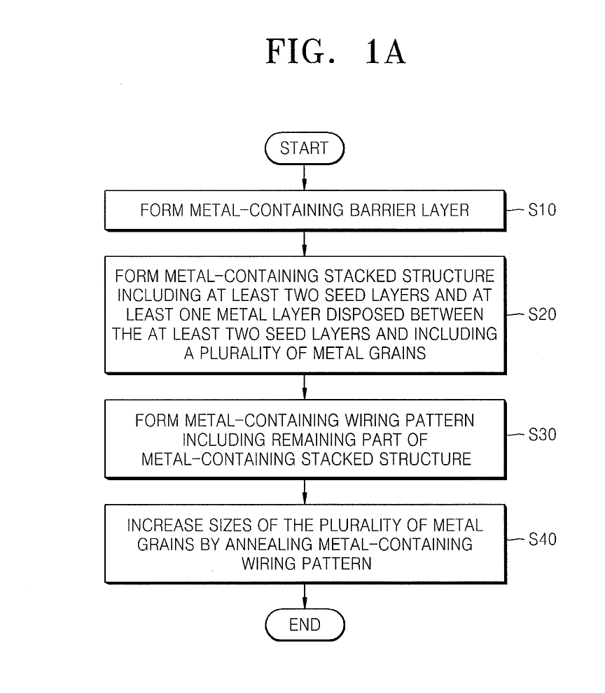

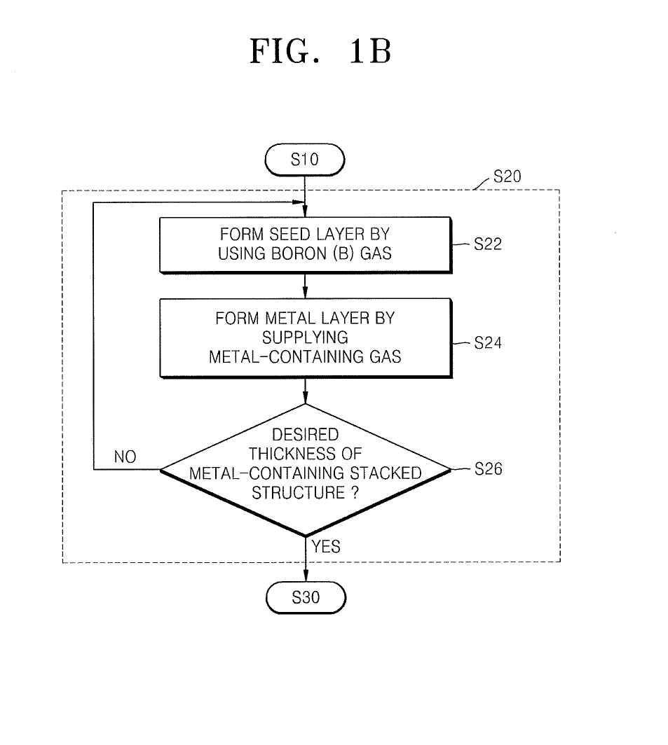

FIGS. 1A and 1B illustrate flowcharts of a method of fabricating a semiconductor device according to an embodiment.

Referring to FIG. 1A, in operation S10, a metal-containing barrier layer may be formed on a semiconductor substrate including a conductive region. The metal-containing barrier layer may be formed on the conductive region. In some embodiments, the metal-containing barrier layer may include at least one of Ti, Ta, TiN, TaN, or TiSiN.

In operation S20, a metal-containing stacked structure may be formed on the metal-containing barrier layer. The metal-containing stacked structure may include at least two seed layers, and at least one metal layer disposed between the at least two seed layers and including a plurality of metal grains. The plurality of metal grains may include at least one of W, Mo, Pt, or Rh.

FIG. 1B illustrates an exemplary method for performing the operation S20.

In operation S22, the seed layer may be formed on the metal-containing barrier layer. In order to form the seed layer, an atomic layer deposition (ALD) process using a boron-containing gas may be used. An ALD process cycle may include supplying the boron-containing gas onto the metal-containing barrier layer, performing a purge operation, supplying a metal-containing gas, and performing a purge operation. The ALD process cycle may be repeatedly performed, e.g., performed three to ten times, in order to form the seed layer. The boron-containing gas may be, e.g., B₂H₆ gas. If a tungsten layer is formed as the metal layer, the metal-containing gas may be, e.g., WF₆ gas. The seed layer may be formed to a thickness of at least 30 Å.

In operation S24, the metal-containing gas may be supplied onto the seed layer to form the metal layer. The metal-containing gas may be variously selected according to the metal layer that is to be formed. The metal-containing gas may include at least one of W, Mo, Pt, or Rh. For example, if the metal layer is a tungsten (W) layer, the metal-containing gas may be WF₆ gas. WF₆ gas and H₂ gas may be supplied onto the seed layer to grow a W film in a chemical vapor deposition (CVD) process. The metal layer may be formed to have a suitable thickness, e.g., the metal layer may be formed to a thickness of about 100 to about 500 Å.

In operation S26, a determination may be made as to whether the metal-containing stacked structure is of a desired thickness. If the overall thickness of the metal-containing stacked structure is less than the desired thickness, the operations S22 and S24 may be repeated. In operation S26, if it is determined that the overall thickness of the metal-containing stacked structure is the desired thickness, operation S30 shown in FIG. 1A may be performed.

In operation S30 of FIG. 1A, a part of the metal-containing stacked structure may be etched to form a metal-containing wiring pattern including a remaining part of the metal-containing stacked structure.

In operation S40, the metal-containing wiring pattern may be annealed to increase sizes of the plurality of metal grains included in the metal-containing wiring pattern. The annealing of the metal-containing wiring pattern may be performed at a temperature in a range of about 800 to about 1000° C. The annealing of the metal-containing wiring pattern may be performed under an atmosphere of at least one gas of H₂, N₂, and Ar gas.

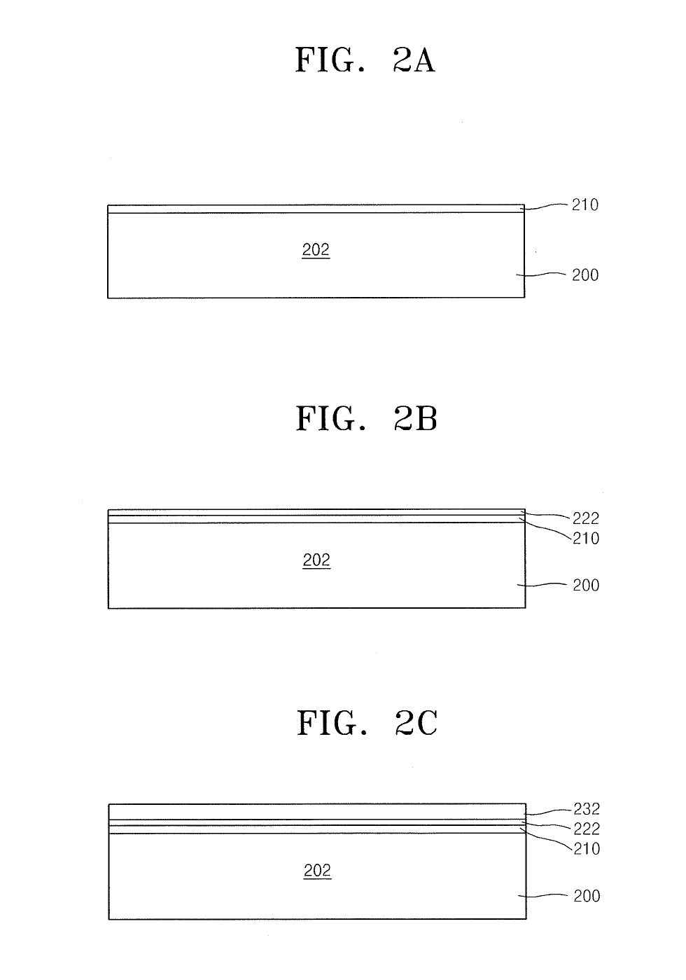

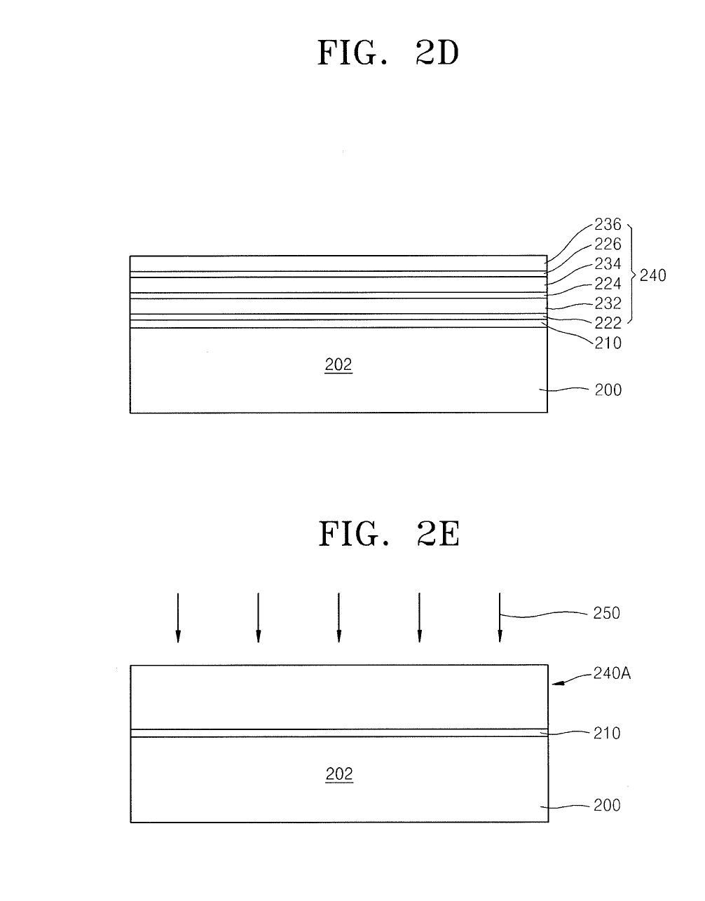

FIGS. 2A, 2B, 2C, 2D, and 2E illustrate cross-sectional views of stages in a process of fabricating a semiconductor device according to an embodiment.

Referring to FIG. 2A, a metal-containing barrier layer 210 may be formed on a conductive region 202 of a semiconductor substrate 200. The metal-containing barrier layer 210 may include at least one of Ti, Ta, TiN, TaN, and TiSiN. For example, the metal-containing barrier layer 210 may be formed of TiN, Ti\TiN, TaN, Ta\TaN, or TiSiN. The metal-containing barrier layer 210 may be formed using, e.g., an ALD process or a CVD process. The metal-containing barrier layer 210 may be formed to a thickness of, e.g., about 20 to 100 Å.

Referring to FIG. 2B, a first seed layer 222 may be formed on the metal-containing barrier layer 210. The first seed layer 222 may be formed in an ALD process by using a B₂H₆ gas. The first seed layer 222 may be formed to a thickness of at least 30 Å. The first seed layer 222 may be an amorphous seed layer including B atoms and W atoms. The ALD process may include an ALD process cycle including supplying the B₂H₆ gas onto the metal-containing barrier layer 210, performing a purge operation, supplying the WF₆ gas, and performing a purge operation. The ALD process cycle may be repeatedly performed, e.g., performed three to ten times, in order to form the first seed layer 222. If the first seed layer 222 is formed in the above processes, the first seed layer 222 may include the W atoms and the B atoms.

Referring to FIG. 2C, a first metal layer 232 may be formed on the first seed layer 222. The first metal layer 232 may be formed to include at least one of W, Mo, Pt, and Rh. The first metal layer 232 may be formed in the CVD process. For forming the first metal layer 232, a W layer may be grown on the first seed layer 222 by the CVD process after supplying the WF₆ gas and H₂ gas onto the first seed layer 222. The first metal layer 232 may be formed to a suitable thickness, e.g., a thickness of about 50 to 500 Å.

Referring to FIG. 2D, a second seed layer 224, a second metal layer 234, a third seed layer 226, and a third metal layer 236 may be sequentially formed on the first metal layer 232. The second seed layer 224 and the third seed layer 226 may be formed in the same fabrication processes as those used to form the first seed layer 222 described with reference to FIG. 2B, or a different fabrication process may be used to form each seed layer. In addition, the second metal layer 234 and the third metal layer 236 may be formed in the same processes as those used to form the first metal layer 232 described with reference to FIG. 2C, or a different fabrication process may be used to form each metal layer.

Referring to FIG. 2D, through the above processes, a metal-containing stacked structure 240 may be formed on the metal-containing barrier layer 210. The metal-containing stacked structure 240 may include three seed layers including the first, second, and third seed layers 222, 224, and 226, and three metal layers including the first, second, and third metal layers 232, 234, and 236. The first, second, and third metal layers 232, 234, and 236 may be formed on the respective first, second, and third seed layers 222, 224, and 226. If the metal layers are formed in the CVD process, the sizes of the plurality of metal grains forming the metal layers may be in proportion to the thickness of the metal layers. Therefore, the size of each of the metal grains that form the first, second, and third metal layers 232, 234, and 236 (which may have small thicknesses relative to a sum of the thicknesses of the first, second, and third metal layers 232, 234, and 236) may be smaller than a size of each of the metal grains forming a metal layer having a thickness corresponding to a sum of the thicknesses of the first, second, and third metal layers 232, 234, and 236. Therefore, in order to form the metal layer having a desired thickness, the first, second, and third metal layers 232, 234, and 236 may be repeatedly formed, and thus, the metal layer including relatively small metal grains may be formed.

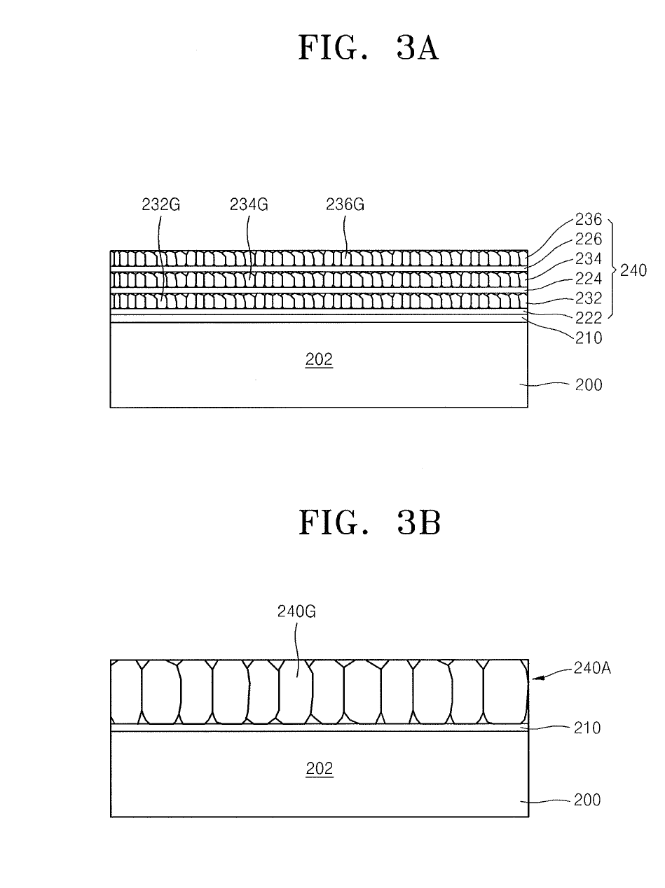

FIG. 3A illustrates a cross-sectional view of a plurality of metal grains forming first, second, and third metal layers, which are included in the metal-containing stacked structure shown in FIG. 2D.

Although not shown in the drawings, unnecessary portions of the metal-containing stacked structure 240 may be etched from the resulting structure shown in FIG. 2D. The first, second, and third metal layers 232, 234, and 236 may include the plurality of metal grains 232G, 234G, and 236G having relatively small diameters that are densely formed. Thus, it may be possible to obtain a smooth morphology of an etched surface of the metal-containing stacked structure 240 remaining on the semiconductor substrate 200 after the etching process. The metal grains 232G, 234G, and 236G having relatively small diameters may be small relative to metal grains included in a metal layer having a thickness corresponding to a sum of the thicknesses of the first, second, and third metal layers 232, 234, and 236.

Referring to FIG. 2E, the metal-containing stacked structure 240 may be treated by heat 250 so as to form a metal-containing conductive line 240A in which the sizes of the plurality of metal grains are increased. The treatment of the metal-containing stacked structure 240 by the heat 250 may be performed at a temperature in a range of, e.g., about 800 to about 1000° C. If the temperature of the heat 250 is in a range of about 800 to about 1000° C., the metal grains may be sufficiently grown in the metal-containing stacked structure 240, and other unit devices that are formed on the semiconductor substrate 200 may not be degraded due to the heat. The time during which the metal-containing stacked structure 240 is treated by the heat 250 may be a suitable time, that is, the treatment by the heat 250 may be performed for a time during which the sizes of the metal grains in the metal-containing conductive line 240A may be sufficiently increased. For the treatment by the heat 250, rapid thermal processing (RTP), spike rapid thermal annealing (RTA), flash annealing, or furnace annealing processes may be performed. The treatment of the metal-containing stacked structure 240 by the heat 250 may be performed under a non-oxidizing atmosphere. The treatment of the metal-containing stacked structure 240 by the heat 250 may be performed under an atmosphere of at least one gas of H₂, N₂, and Ar gas. For example, during performing of the treatment by the heat 250, an atmospheric gas may include only H₂, only N₂, or a mixture gas of H₂ and N₂. If the heat process 250 is performed under H₂ atmosphere, oxidation of the metal included in the metal-containing stacked structure 240 may be prevented. The B atoms that may be included in the first, second, and third seed layers 222, 224, and 226 may be dispersed in the metal-containing stacked structure 240 due to the treatment by the heat 250, and the B atoms may remain in the metal-containing conductive line 240A obtained after the treatment by the heat 250.

FIG. 3B illustrates a cross-sectional view of a plurality of metal grains forming a metal-containing conductive line shown in FIG. 2E. When comparing FIGS. 3A and 3B with each other, sizes of the metal grains 240G included in the metal-containing conductive line 240A obtained after the treatment by the heat 250 are increased compared to the sizes of the metal grains 232G, 234G, and 236G. Diameters of the metal grains 240G in the metal-containing conductive line 240A may approximately correspond to the overall thickness of the metal-containing stacked structure 240.

With reference to FIGS. 2A through 2E, the metal-containing stacked structure 240 may be include three seed layers, that is, the first, second, and third seed layers 222, 224, and 226, and three metal layers, that is, the first, second, and third metal layers 232, 234, and 236. However, any suitable number of seed layers and metal layers may be included in the metal-containing stacked structure, e.g., two, four, or more seed layers and two, four, or more metal layers, and the metal-containing stacked structure may include these seed layers and metal layers stacked alternately with each other.

The metal-containing conductive line 240A obtained through the processes shown in FIGS. 2A through 2E may be used as a suitable conductive layer in the semiconductor device. For example, the metal-containing conductive line 240A may form word lines, bit lines, contact plugs for electrically connecting a plurality of conductive layers with each other, or various wiring lines.

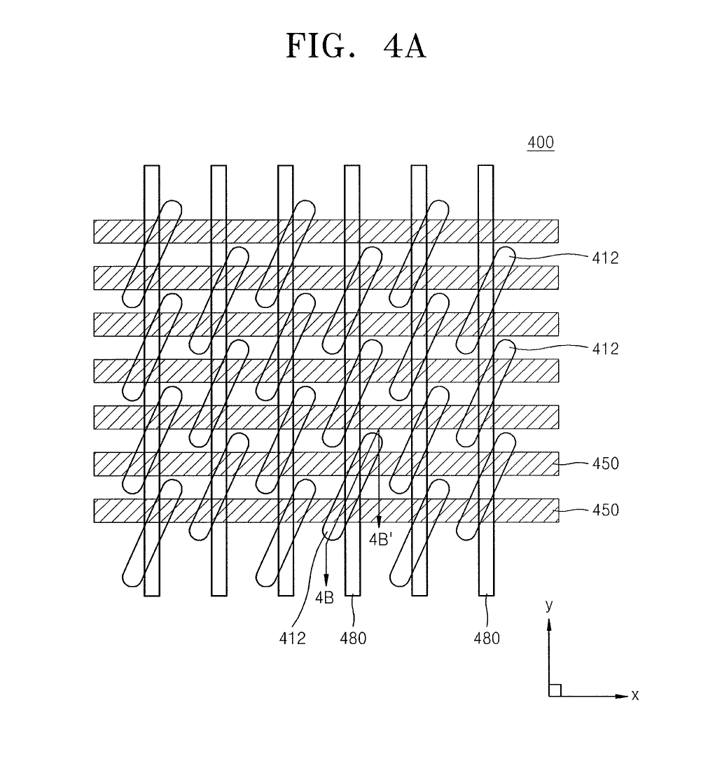

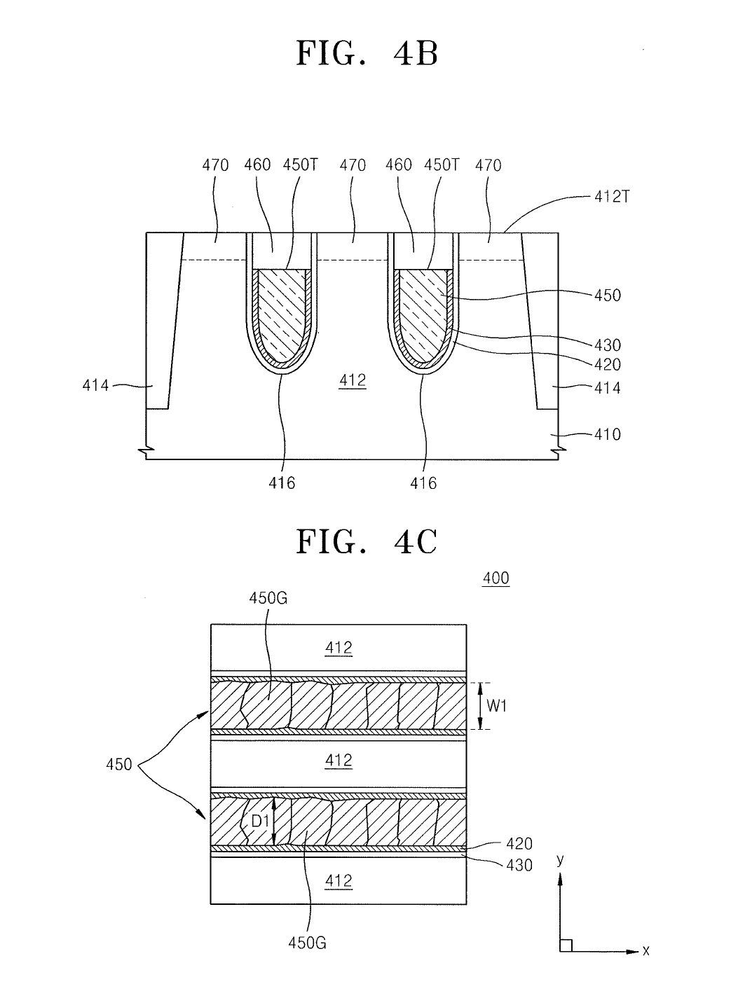

FIG. 4A illustrates a layout of a semiconductor device according to an embodiment. FIG. 4B illustrates a cross-sectional view of the semiconductor device taken along line 4B-4B′ of FIG. 4A. FIG. 4C illustrates a plan view of buried word lines 450 shown in FIGS. 4A and 4B, and other components. The semiconductor device 400 shown in FIGS. 4A, 4B, and 4C may be included in a memory cell region of a dynamic random access memory (DRAM) device.

Referring to FIGS. 4A, 4B, and 4C, the semiconductor device 400 may include an isolation layer 414 defining a plurality of active areas 412 on a semiconductor substrate 410. The semiconductor substrate 410 may be formed of a semiconductor material such as silicon (Si).

A plurality of trenches 416 that extend across the active areas 412 and the isolation layer 414 may be formed on the semiconductor substrate 410. A plurality of buried word lines 450 having upper surfaces 450T that are located at a lower level than upper surfaces 412T of the active areas 412 may extend in the trenches 416 in an x-axis direction (referring to FIGS. 4A and 4C). That is, upper surfaces 450T of the buried word lines 450 may be below upper surfaces 412T of the active areas 412, such that the upper surfaces 450T are between a bottom of the trenches 416 and the upper surface 412T.

Source/drain regions 470 may be exposed on the upper surfaces 412T of the active areas 412. A plurality of bit lines 480 (refer to FIG. 4A) may be formed on the semiconductor substrate 410. The plurality of bit lines 480 may extend in a y-axis direction (referring to FIG. 4A) that is perpendicular to the direction in which the buried word lines 450 are extended.

A gate dielectric layer 420 and a metal-containing barrier layer 430 may be formed between the buried word lines 450 and the active regions 412.

The gate dielectric layer 420 may be formed to extend along an inner wall of the trench 416 while directly contacting the active region 412 in the inner wall of the trench 416. The gate dielectric layer 420 may be formed of a silicon oxide film, and the gate dielectric layer 420 may be formed of a layer having a high dielectric constant such as, e.g., hafnium oxide film (HfO₂).

The metal-containing barrier layer 430 may extended along the inner wall of the trench 416 on the gate dielectric layer 420 that is formed in the trench 416. The metal-containing barrier layer 430 may define a wiring space having a first width (W1) in the y direction (refer to FIGS. 4A and 4C) in the trench 416. Other details about the metal-containing barrier layer 430 may be the same as the metal-containing barrier layer 210 described with reference to FIG. 2A.

The buried word line 450 may be formed within the wiring space having the first width W1. The buried word line 450 may include a plurality of metal grains 450G, each having a particle diameter D1 that is the same as the first width W1, in the y-axis direction (refer to FIGS. 4A and 4C). The plurality of metal grains 450G may be formed of at least one of W, Mo, Pt, and Rh. The buried word line 450 may further include B atoms that are dispersed in the buried word line 450.

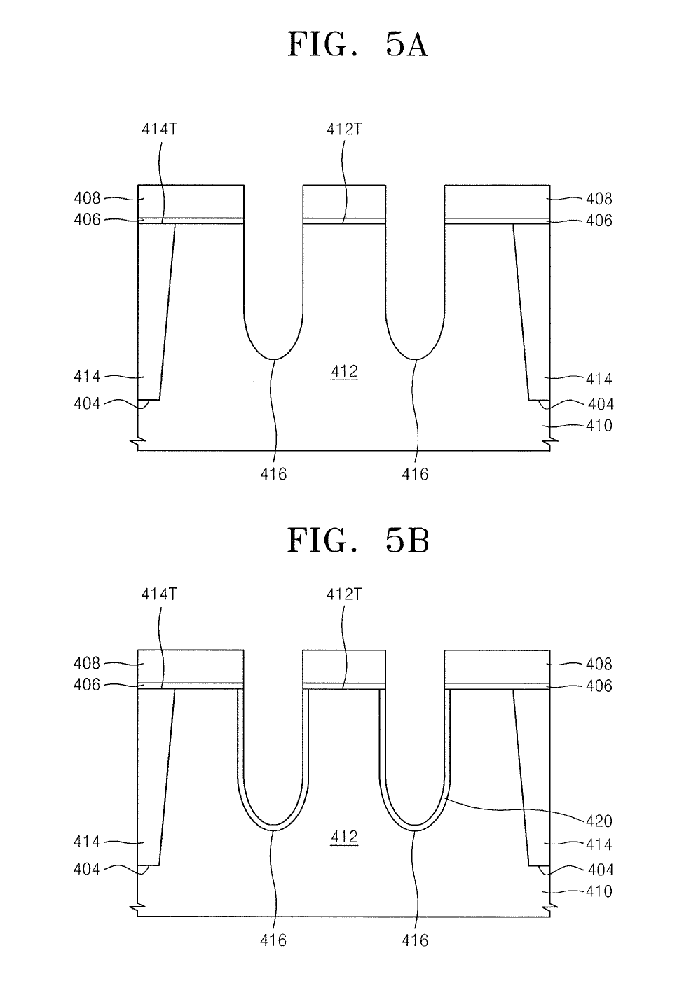

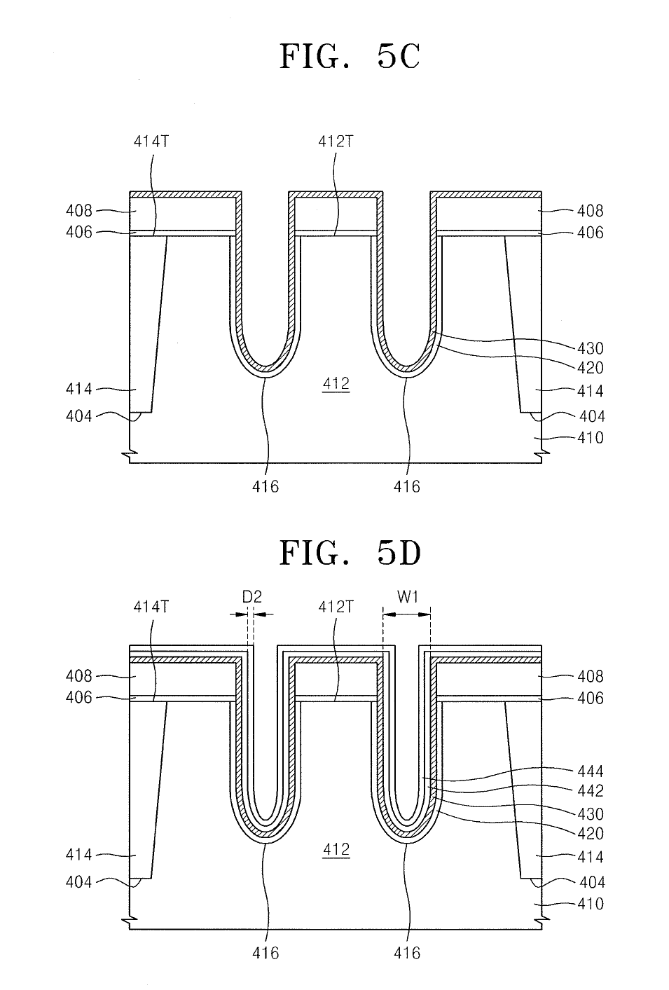

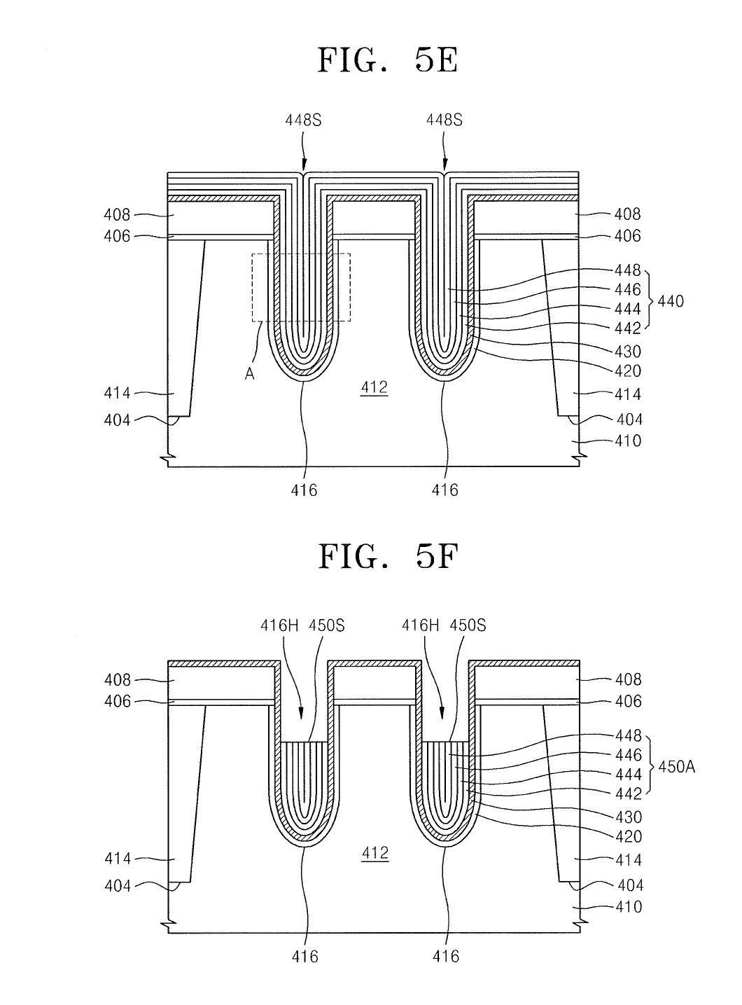

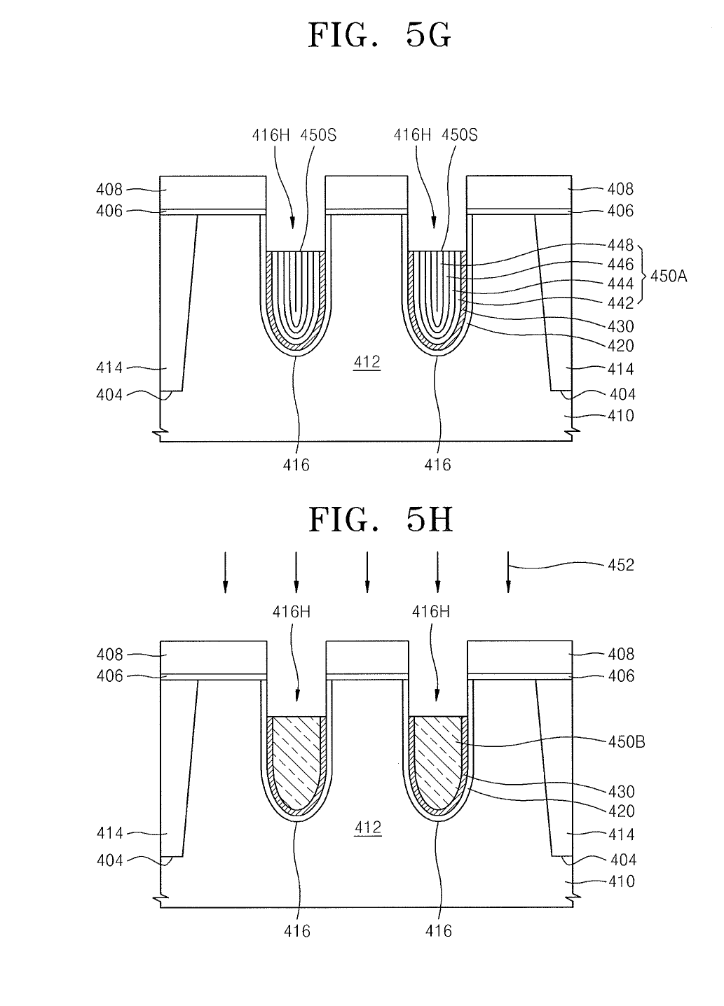

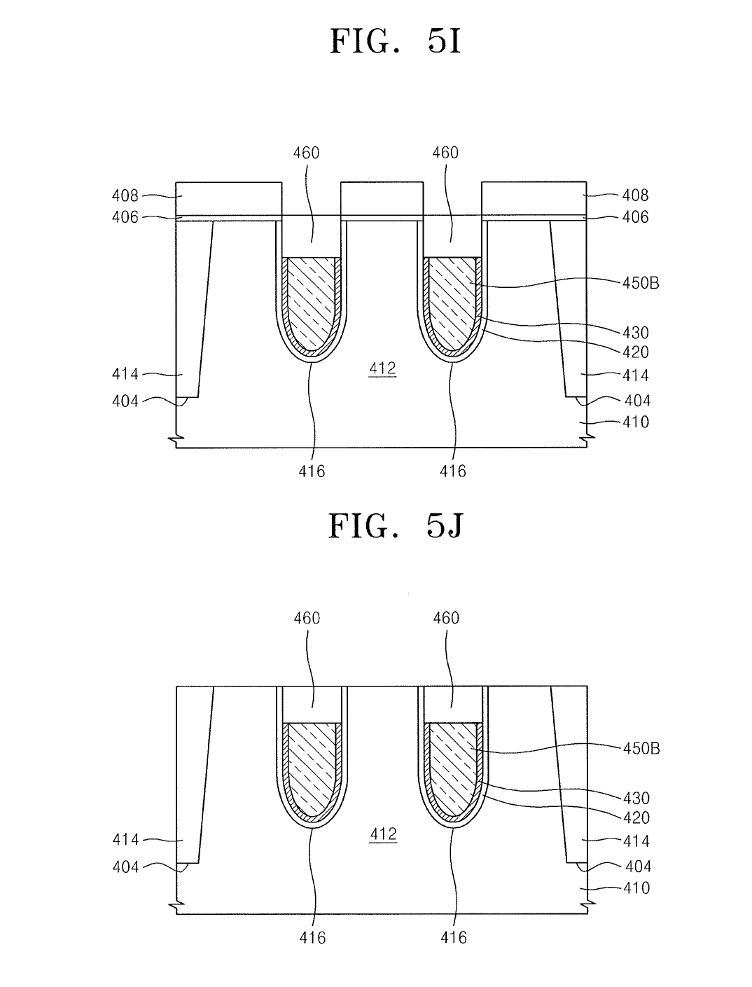

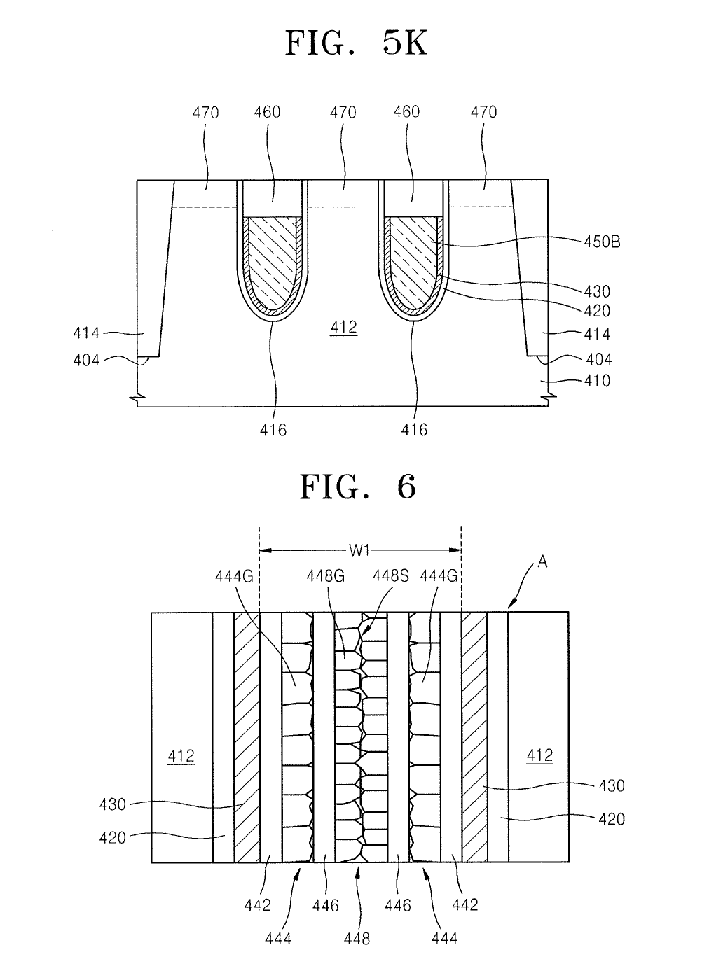

FIGS. 5A, 5B, 5C, 5D, 5E, 5F, 5G, 5H, 5I, 5J, and 5K illustrate cross-sectional views of stages in a process of fabricating a semiconductor device according to an embodiment, in a fabrication order. In FIGS. 5A through 5K, like reference numerals as those of FIGS. 4A through 4C denote like elements, and detailed descriptions thereof will not be repeated here.

FIGS. 5A through 5K illustrate cross-sections corresponding to the cross-section taken along a line 4B-4B′ of FIG. 4A shown in FIG. 4B.

Referring to FIG. 5A, the isolation layer 414 may be formed on the semiconductor substrate 410 in order to define the plurality of active areas 412. A shallow trench isolation (STI) process may be performed to form the isolation layer 414. The isolation layer 414 may have a structure in which a thermal oxide layer (not shown) covering an inner wall of a isolation trench 404 formed in the semiconductor substrate 410, a nitride liner (not shown) formed on the thermal oxide layer, and an oxide layer (not shown) filling inner portions of the isolation trench 404 are sequentially stacked.

A stacked structure including a pad oxide layer pattern 406 and a mask pattern 408 may be formed on the semiconductor substrate 410, in which the isolation layer 414 is formed. The stacked structure of the pad oxide layer pattern 406 and the mask pattern 408 may expose parts of the upper surfaces 412T of the active areas 412, and parts of the upper surfaces 414T of the isolation layer 414 where the trenches 416 are to be formed. The mask pattern 408 may include a hard mask pattern formed of a nitride layer or a polysilicon layer. In an implementation, the mask pattern 408 may be a stacked structure including the hard mask pattern and a photoresist pattern.

Then, the exposed active areas 412 and the isolation layer 414 may be etched by using the mask pattern 408 as an etching mask so as to form the plurality of trenches 416 that extend across the plurality of active areas 412 and the isolation layer 414 in the semiconductor substrate 410. The plurality of trenches 416 may be formed as a plurality of line patterns that extend in parallel with each other in a predetermined direction (an x-axis direction in FIG. 4A) in the semiconductor substrate 410.

Referring to FIG. 5B, the gate dielectric layer 420 may be formed on surfaces of the active areas 412, which are exposed by inner walls of the trenches 416. A thermal oxidizing process or a radical oxidizing process may be performed with respect to the exposed surfaces of the active areas 412 in the inner walls of the trenches 416 so as to form the gate dielectric layer 420.

Referring to FIG. 5C, the metal-containing barrier layer 430 may be formed on the gate dielectric layer 420. The metal-containing barrier layer 430 may be formed by the CVD process or the ALD process.

Referring to FIG. 5D, a first seed layer 442 may be formed on the metal-containing barrier layer 430, and a first metal layer 444 may be formed on the first seed layer 442.

The first seed layer 442 may be formed by using the same process for forming the first seed layer 222 described with reference to FIG. 2B. The first seed layer 442 may extend along the inner wall of the trench 416 on the metal-containing barrier layer 430, and may be formed to a thickness of at least 30 Å.

The first metal layer 444 may be formed by using the same process for forming the first metal layer 232 described with reference to FIG. 2C. The first metal layer 444 may extend along the inner wall of the trench 416 on the first seed layer 442. The first metal layer 444 may be formed by the CVD process. The first metal layer 444 may be formed to have a thickness D2 that is less than ½ of the width W1 of the wiring space. The width W1 of the wiring space may be defined by the metal-containing barrier layer 430 along the width direction of the trench 416, in particular, a y-axis direction (refer to FIG. 4A), in the trench 416. That is, the width WI of the wiring space may be the distance between two parts of the metal-containing barrier layer 430 that are on opposite sides of the inner wall relative to a center of the trench 416. Sizes of a plurality of metal grains included in the first metal layer 444 may be limited by the thickness of the first metal layer 444. The thickness of the first metal layer 444 may be reduced. Thus, the sizes of the plurality of metal grains forming the first metal layer 444 may also be reduced.

The first metal layer 444 may be formed to a suitable thickness, e.g., a thickness of about 50 to about 500 Å. The thickness of the first metal layer 444 may vary depending on the width of the trench 416, and the number of seed layers and metal layers formed in the trench 416 may also vary. For example, if the width W2 of the trench 416 is about 300 Å, the first seed layer 442 may be formed to a thickness of about 30A and the first metal layer 444 may be formed to a thickness of about 50 Å.

Referring to FIG. 5E, the second seed layer 446 may be formed on the first metal layer 444, and the second metal layer 448 may be formed on the second seed layer 446. The second seed layer 446 and the second metal layer 448 may be formed in similar processes to those used to form the first seed layer 446 and the first metal layer 444 described with reference to FIG. 5D. However, as shown in FIG. 5E, the second metal layer 448 may be formed to completely fill the inside of the trench 416. If more than two metal layers are used, the last metal layer formed may completely fill the inside of the trench 416. The first seed layer 442, the first metal layer 444, the second seed layer 446, and the second metal layer 448 may constitute a metal-containing stacked structure 440 that fills in the wiring space of the trench 416.

The second metal layer 448 may be formed by the CVD process. Thus, the plurality of metal grains may be gradually grown while facing each other in the trench 416, and may contact each other in a center portion of the trench 416 as shown in FIG. 5E. In addition, after forming the second metal layer 448, a seam portion 448S may be formed as a line that may remain at a center portion of the trench 416 along a length direction of the trench 416 (a direction corresponding to the x-axis direction of FIG. 4A).

FIG. 6 illustrates a cross-sectional view showing an expanded view of region A denoted by the dotted lines in FIG. 5E, for describing the seam portion 448S in more detail. In FIG. 6, the plurality of metal grains 444G and 448G that may form the first metal layer 444 and the second metal layer 448 are illustrated for convenience of description. When the second metal layer 448 is formed, the plurality of metal grains 448G may be grown from a surface of the second seed layer 446 toward the center portion of the trench 416 by the CVD process. The diameter of the metal grains 444G and 448G may be less than about ½ of the width W1, and may be between about 1/10 and about ⅖ of the width W1. During the growing of the plurality of metal grains 448G, the plurality of metal grains 448G may fill the center portion in the trench 416. Thus, the plurality of metal grains 448G that are grown while facing each other may contact each other at the center portion in the trench 416. The trench 416 may be filled by the second metal layer 448 and there may be no empty space in the trench 416. Thus, the seam portion 448S may extend continuously or intermittently along the length direction of the trench 416 at the center portion in the trench 416.

Each of the first and second metal layers 444 and 448 (which may have small thicknesses relative to the width W1 of the wiring space) may include the plurality of metal grains 444G or 448G that have relatively small particle diameters and are densely formed. Thus, the inside of the trench 416 may be densely filled without a void. The relatively small particle diameters of the plurality of metal grains 444G or 448G may be small relative to the width W1 of the wiring space.

Referring to FIG. 5F, the metal-containing stacked structure 440 formed on the metal-containing barrier layer 430 may be etched-back from the upper portion of the metal-containing stacked structure 440 so that a metal-containing wiring pattern 450A may be formed. The metal-containing wiring pattern 450A may include the remaining portion of the metal-containing stacked structure 440 in the trench 416 after the etch-back. Thus, the metal-containing barrier layer 430 may be exposed on the upper portion of the semiconductor substrate 410, and a recess hole 416H may be formed on an inlet portion of the trench 416 (that is, the upper portion of the metal-containing wiring pattern 450A in the trench 416). The etch-back of the metal-containing stacked structure 440 may be performed by using, e.g., a dry-etching process. The etch-back of the metal-containing stacked structure 440 may remove portions of the metal-containing stacked structure 440 such than an upper surface 450S of the metal-containing wiring pattern 450A is between a bottom of the trench 416 and an upper surface of the active areas 412 or an upper surface of the gate dielectric layer 420. The etch back of the metal-containing stacked structure 440 may be the first time a portion of the metal-containing stacked structure 440 is removed. That is, in an embodiment, the metal-containing stacked structure 440 may be formed by only deposition, without any substantial portion of the metal-containing stacked structure 440 being removed before the etch-back that forms the metal-containing wiring pattern 450A.

The first and second metal layers 444 and 448 may include the plurality of metal grains 444G and 448G that have relatively small particle diameter and are densely formed. The relatively small particle diameter of metal grains 444G and 448G may be small relative to the width W1 of the wiring space. Grain boundaries of the plurality of metal grains 444G and 448G may affect a morphology variation on upper surfaces 450S of the plurality of metal-containing wiring patterns 450A formed on the semiconductor substrate 410 after performing the etch-back process. That is, if the particle diameters of the plurality of metal grains 444G and 448G are large, the morphology variation may increase, and if the particle diameters of the plurality of metal grains 444G and 448G are small, the morphology variation may be reduced. When etching-back the first and second seed layers 442 and 446 and the first and second metal layers 444 and 448, the first and second metal layers 444 and 448 may include the plurality of metal grains 444G and 448G having the relatively small particle diameters. Thus, the morphology variation of the upper surfaces 450S of the metal-containing wiring patterns 450A that are obtained after the etch-back process is performed may be reduced. In addition, variation in the morphology on the plurality of metal-containing wiring patterns 450A that are formed in the plurality of trenches 416 may be reduced throughout the entire region of the semiconductor substrate 410, and accordingly, the morphology uniformity may be increased. Therefore, scattering degradation of threshold voltages V of a plurality of cell transistors that are formed using the metal-containing wiring patterns 450A may be prevented.

Referring to FIG. 5G, exposed portions of the metal-containing barrier layer 430 may be removed so that the portions of the metal-containing barrier layer 430, which are located under an upper surface 450S of the metal-containing wiring patterns 450A, may remain. In order to remove the exposed portions of the metal-containing barrier layer 430, a wet-etching process may be performed. Thus, some parts of the gate dielectric layer 420 may be exposed on side walls of the recess holes 416H.

Referring to FIG. 5H, a resulting structure including the metal-containing wiring patterns 450A may be annealed by a treatment by heat 452 so as to increase the sizes of the metal grains 444G and 448G included in the metal-containing wiring patterns 450A. Accordingly, conductive lines 450B including a plurality of metal grains having increased sizes may be obtained. The conductive lines 450B may form the buried word lines 450 shown in FIGS. 4A through 4C, and may include a plurality of metal grains 450G, each having a particle diameter corresponding to the width WI of the wiring space that is defined by the metal-containing barrier layer 430, as shown in FIG. 4C.

Details for the treatment by the heat 452 may be similar to the treatment of the metal-containing stacked structure 240 by the heat 250 described with reference to FIG. 2E.

The B atoms that may be included in the first and second seed layers 442 and 446 may be dispersed in the metal-containing wiring patterns 450A by the treatment by the heat 452, and may remain in a dispersed state in the metal-containing conductive lines 450B obtained after the heat process.

Referring to FIG. 5I, an insulating layer (not shown) may be formed on the metal-containing barrier layer 430, the metal-containing conductive lines 450B, and the mask pattern 408 so as to completely fill inner spaces of the recess holes 416H. After that, the insulating layer may be etched back so that the mask pattern 408 may be exposed and capping layers 460 may be formed in the recess holes 416H. The insulating layer may be polished, e.g., by a chemical mechanical polishing (CMP) process, to form the capping layers 460. The capping layers 460 may be formed of, e.g., nitride layers or oxide layers. The mask pattern 408 may also be polished along with the insulating layer.

Referring to FIG. 5J, the mask pattern 408 and the pad oxide layer pattern 406 may be removed from the resulting structure in which the capping layers 460 may be formed as shown in FIG. 51, and thus, upper surfaces of the active areas 412 may be exposed. The mask pattern 408 and the pad oxide layer pattern 406 may be removed by the wet etching process. If the capping layers 460 are nitride layers and the mask pattern 408 is an oxide layer, the mask pattern 408 and the pad oxide layer pattern 406 may be removed by a wet-etching process that uses a difference between the etch-selectivity of the capping layers 460 and the mask pattern 408 and the pad oxide layer pattern 406.

Referring to FIG. 5K, source/drain regions 470 may be formed on the upper surfaces of the active areas 412 by implanting impurity ions into the upper surface of the active areas 412. The ion implantation for forming the source/drain regions 470 may be performed simultaneously with an ion implantation for forming source/drain regions of peripheral circuit transistors (not shown) formed on peripheral circuit regions (not shown) of the semiconductor substrate 410. The ion implantation for forming the source/drain regions 470 may also be performed after forming the isolation layer 414 and before forming the trenches 416 in the semiconductor substrate 410, as in FIG. 5A.

With reference to FIGS. 5A through 5K, the metal-containing stacked structure 440 is illustrated as including two seed layers, that is, the first and second seed layers 442 and 446, and two metal layers, that is, the first and second metal layers 444 and 448. However, a metal-containing stacked structure including three or more seed layers and three or more metal layers, which are stacked alternately with each other, may be formed.

With reference to FIGS. 5A through 5K, if the metal-containing conductive lines 450B are formed from the metal-containing stacked structure 440 including a plurality of metal layers having relatively small thicknesses, (i.e., the first and second metal layers 444 and 448 are formed first, and then an etch-back process for removing portions in the stacked structure is performed, and then the remaining stacked structure after the etch-back process is annealed to increase the sizes of the metal grains so as to form the conductive lines) the metal-containing conductive lines 450B may provide desired electric properties. The etch-back process may be performed on the plurality of metal layers formed to have relatively small thicknesses that include the small-sized metal grains. Thus, the surface morphology characteristics of the stacked structure remaining after the etch-back process may be improved, and the variation between the morphology of the plurality of metal-containing wiring patterns may be reduced. Therefore, the morphology uniformity of the semiconductor substrate may be increased. The conductive lines that are formed in the above process may be used as the word lines of a transistor. Thus, the scattering degradation of the threshold voltage V may be prevented. In addition, as shown in FIG. 5H, the sizes of the plurality of metal grains 450G may be increased due to the annealing process. Therefore, the conductive lines 450B including the metal grains 450G (the sizes of which are increased) may be used as the buried word lines 450, and thus, resistance may be reduced.

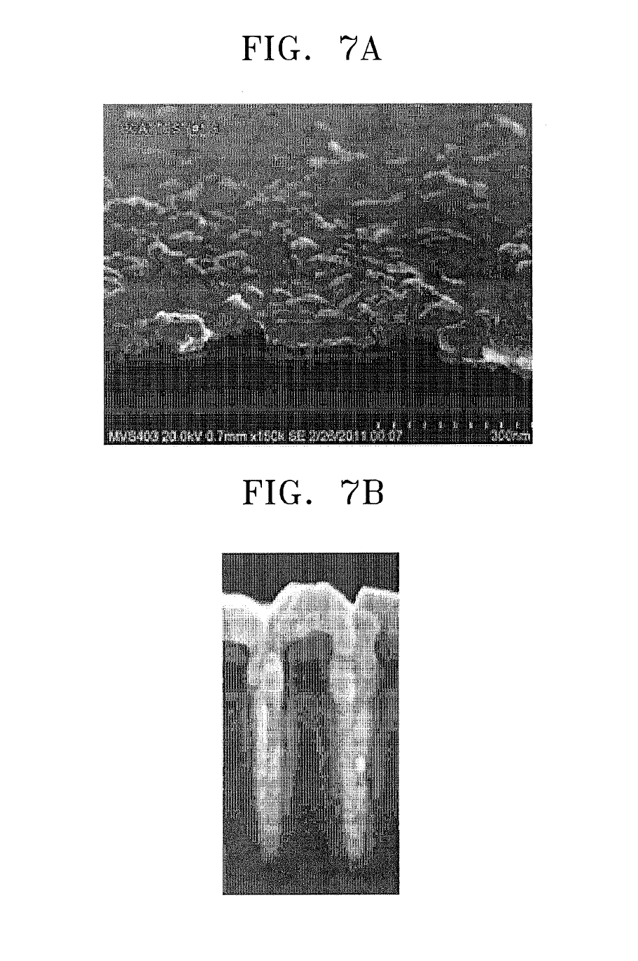

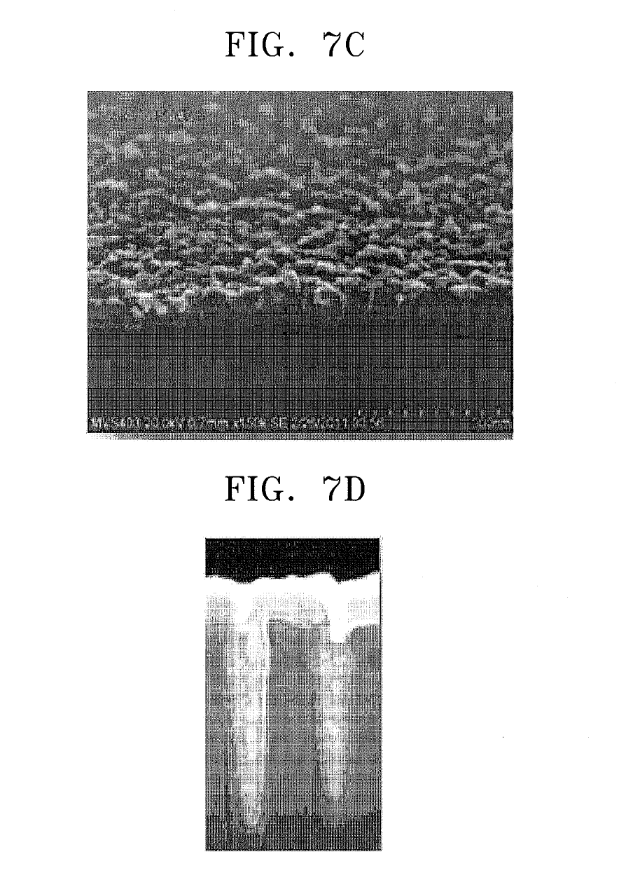

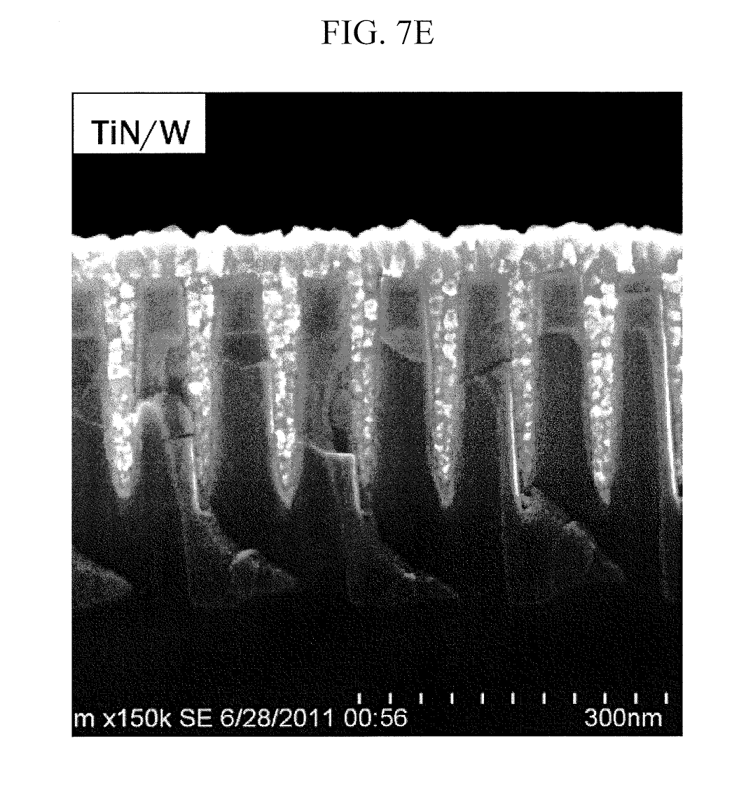

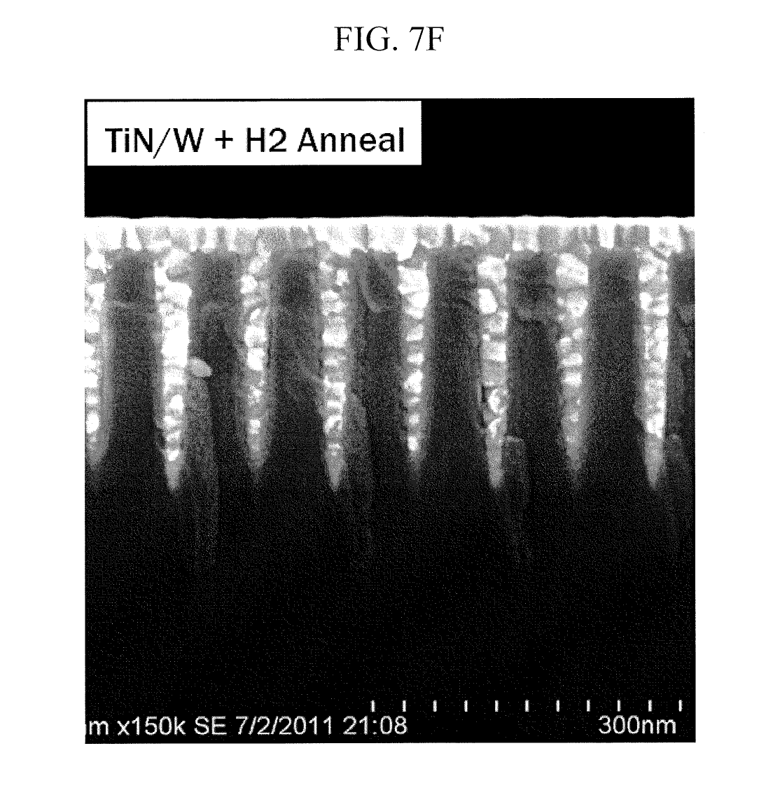

FIGS. 7A through 7D are scanning electron microscope (SEM) images that allow comparison of the surface morphologies when a bulk W layer having a relatively small thickness is separately formed on a separate seed layer a plurality of times, and when the bulk W layer is formed once to a relatively large thickness. FIGS. 7A and 7B illustrate SEM images for evaluating surface morphologies of bulk W films formed by a method of fabricating a semiconductor device from a metal layer having a relatively large thickness. FIGS. 7C and 7D illustrate SEM images for evaluating surface morphologies of bulk W films formed by a method of fabricating a semiconductor device from multiple metal layers having relatively small thicknesses.

In more detail, FIGS. 7A and 7B are SEM images illustrating the surface morphology of a metal-containing layer (FIG. 7A) and W grains forming the metal-containing layer (FIG. 7B) when a plurality of trenches are formed in a semiconductor substrate, a TiN barrier layer is formed in the plurality of trenches and on the semiconductor substrate, and the metal-containing layer is formed by sequentially stacking a seed layer having a thickness of 50 Å and a bulk W layer having a thickness of 400 Å on the TiN barrier layer. That is, the metal-containing layer of FIG. 7A and 7B is formed from a single metal layer having a relatively large thickness.

FIGS. 7C and 7D are SEM images showing the surface morphology of the metal-containing stacked structure (FIG. 7C) and W grains forming the metal-containing stacked structure (FIG. 7D) when a plurality of trenches are formed in the semiconductor substrate, a TiN barrier layer is formed in the plurality of trenches and on the semiconductor substrate, and the metal-containing stacked structure is formed by sequentially forming a first seed layer having a thickness of 50 Å, a first bulk W layer having a thickness of 180 Å, a second seed layer having a thickness of 50 Å, and a second bulk W layer having a thickness of 180 Å on the TiN barrier layer. That is, the metal-containing layer of FIG. 7C and 7D is formed from multiple metal layers having relatively small thicknesses.

As shown in FIGS. 7C and 7D, the metal-containing stacked structure may be formed by alternately stacking the seed layers and the bulk W layers having relatively small thicknesses. Thus, the sizes of the metal grains included in the bulk W layer may be reduced, and the surface morphology of the metal-containing stacked structure may be improved.

FIGS. 7E and 7F illustrate SEM images for evaluating the size of W grains before and after annealing of a metal-containing stacked structure. FIG. 7E illustrates the size of W grains before annealing, and FIG. 7F illustrates the size of W grains after annealing. FIGS. 7E and 7F illustrate that the size of W grains may be relatively increased as a result of annealing.

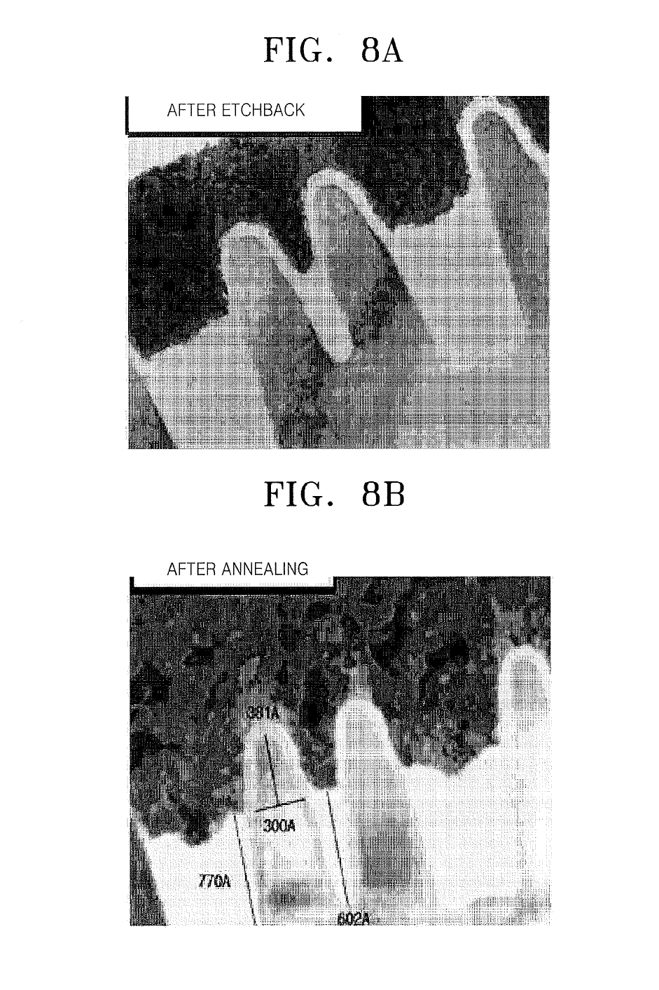

FIGS. 8A and 8B illustrate SEM images for evaluating the effects of an annealing process on a metal-containing stacked structure formed by a method of fabricating a semiconductor device according to an embodiment. In more detail, FIGS. 8A and 8B are SEM images illustrating sizes of W grains before (FIG. 8A) and after (FIG. 8B) annealing with respect to the metal-containing stacked structure, which was obtained by forming a plurality of trenches in the semiconductor substrate, forming the TiN barrier layer in the plurality of trenches and on the semiconductor substrate, and sequentially forming a first seed layer having a thickness of 50 Å, a first bulk W layer having a thickness of 180 Å, a second seed layer having a thickness of 50 Å, and a second bulk W layer having a thickness of 180 Å on the TiN barrier layer.

In more detail, FIG. 8A is a SEM image illustrating a resulting structure after forming the metal-containing stacked structure, and etching-back the metal-containing stacked structure from an upper portion of the metal-containing stacked structure, before annealing.

FIG. 8B is a SEM image illustrating a resulting structure after performing annealing at a temperature of 800° C. and in a H₂ gas atmosphere on the metal-containing stacked structure remaining after the etch-back.

From the comparison of FIGS. 8A and 8B, it is determined that the sizes of the W grains are increased due to the annealing.

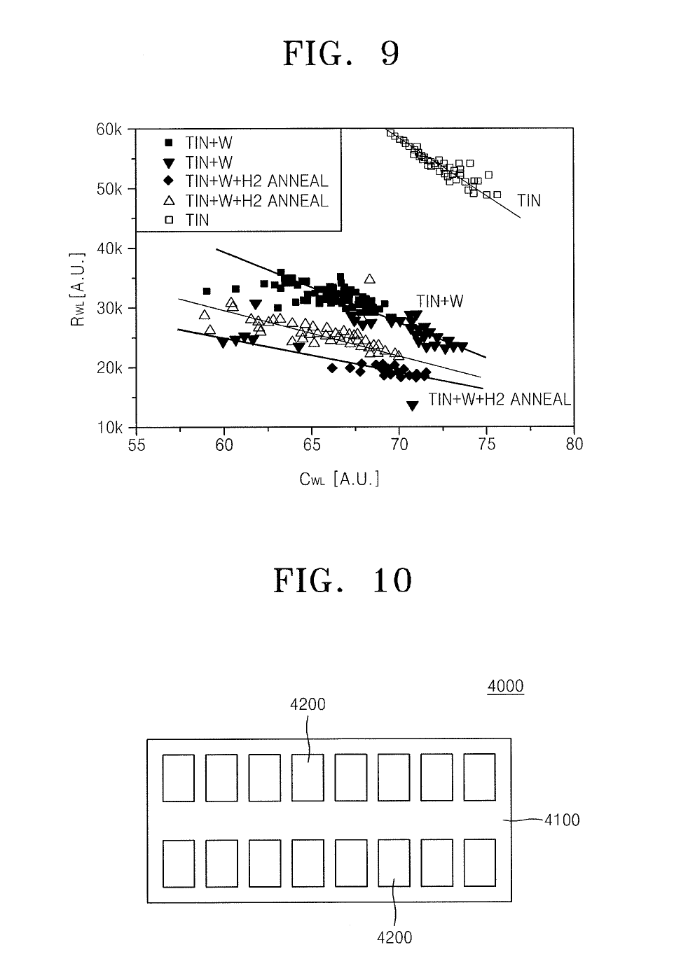

FIG. 9 illustrates a graph showing a resistance reduction effect according to the annealing of a metal-containing stacked structure formed in a plurality of trenches in a semiconductor device according to an embodiment. In more detail, FIG. 9 illustrates a graph showing a variation in the resistance (R_{WL}) before and after the annealing of the metal-containing stacked structure, which is obtained by forming a plurality of trenches in the semiconductor substrate, forming the TiN barrier layer in the plurality of trenches and on the semiconductor substrate, and sequentially forming a first seed layer having a thickness of 50 Å, a first bulk W layer having a thickness of 180 Å, a second seed layer having a thickness of 50 Å, and a second bulk W layer having a thickness of 180 Å on the TiN barrier layer. In the graph of FIG. 9, a transverse axis denotes capacitance (C_{WL}) between two adjacent metal-containing stacked structures, and a longitudinal axis denotes resistance (R_{WL}).

In FIG. 9, marks ▪ and ▾ denote a case where the metal-containing stacked structure is not annealed, a mark ♦ denotes a case where the metal-containing stacked structure is annealed at a temperature of 860° C. under the H₂ gas atmosphere, a mark A denotes a case where the metal-containing stacked structure is annealed at a temperature of 800° C. in the H₂ gas atmosphere, and a mark □ denotes a case where the metal-containing stacked structure is not formed on the TiN barrier layer and the annealing is not performed. In FIG. 9, the marks ▪ and ▾ have metal-containing stacked structures with different heights. The mark ▪ denotes a case where small depth of the metal-containing stacked structure is etched-back from the upper portion thereof, and the mark ▾ denotes a case where large depth of the metal-containing stacked structure is etched-back from the upper portion thereof, such that, after etch-back, the height of the metal-containing stacked structure of the mark ▾ is about 93% of the height of the metal-containing stacked structure of the mark ▪.

As shown in FIG. 9, when the metal-containing stacked structure is annealed, the sizes of the W grains increase in the metal-containing stacked structure, and the resistance is reduced.

FIG. 10 illustrates a plan view of a memory module 4000 including the semiconductor device according to an embodiment.

The memory module 4000 includes a printed circuit board (PCB) 4100 and a plurality of semiconductor packages 4200.

The plurality of semiconductor packages 4200 may include semiconductor devices fabricated by the fabrication method according to an embodiment.

The memory module 4000 according to an embodiment may be a single in-line memory module (SIMM), in which the plurality of semiconductor packages 4200 are mounted on a surface of the PCB 4100, or a dual in-line memory module (DIMM), in which the plurality of semiconductor packages 4200 are mounted on both surfaces of the PCB 4100. In an implementation, the memory module 4000 may be a fully buffered DIMM (FBDIMM) including an advanced memory buffer (AMB) that provides the plurality of semiconductor packages 4200 with external signals.

FIG. 11 illustrates a schematic diagram of a memory card 5000 including the semiconductor device according to an embodiment.

In the memory card 5000, a controller 5100 and a memory 5200 may be disposed to exchange electric signals. For example, when the controller 5100 sends commands, data may be read from the memory 5200.

The memory 5200 may include the semiconductor device fabricated by the method according to an embodiment.

The memory card 5000 may be configured for a suitable memory card, for example, a memory stick card, a smart media card (SM), a secure digital card (SD), a mini-secure digital card (mini SD), and a multimedia card (MMC).

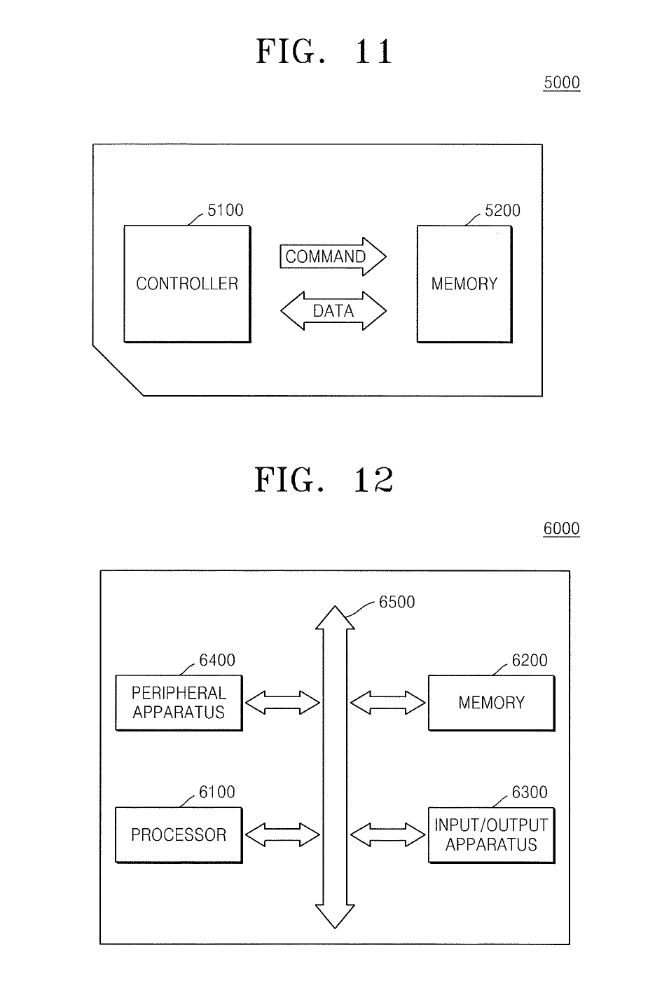

FIG. 12 illustrates a schematic diagram of a system 6000 including the semiconductor device according to an embodiment.

In the system 6000, a processor 6100, an input/output apparatus 6300, and a memory 6200 may communicate data with each other by using a bus 6500.

The memory 6200 may include a random access memory (RAM) and a read only memory (ROM). In addition, the system 6000 may include a peripheral 6400 such as, e.g., a floppy disk drive and a compact disk (CD) ROM drive.

The memory 6200 may include the semiconductor device fabricated by the method according to an embodiment. The memory 6200 may store codes and data for operating the processor 6100. The system 6000 may be used in, e.g., mobile phones, MP3 players, navigators, portable multimedia players (PMPs), solid state disks (SSDs), or household appliances.

By way of summation and review, it may be advantageous to form buried type wires, for example, buried type word lines, in trenches of a semiconductor substrate of a semiconductor device that has a reduced feature size and reduced design rules. It may also be advantageous for the buried type wires to have a low resistance.

The resistance of the buried word line may be reduced by using, e.g., TiN+W, which has a lower resistivity than that of TiN. However, if a dimension of the buried word line is reduced, e.g., to about 20 nm or less, the grain size of the buried W may also be reduced and resistance may increase. Therefore, it may be advantageous for the grain size of the buried W to be increased to reduce the resistance. However, depositing buried W with increased grain size may result in defective local dispersion due to W grain boundaries during a W etch-back process, which may result in degrading the threshold voltage V dispersion of a cell transistor.

By repeatedly depositing a seed layer and a bulk layer, the size of the W grains may be reduced, and the grain and surface morphology of the buried W in the trench may be improved. The stacked structure of the seed and bulk layers may be etched-back to form a desired structure, and then the stacked structure of the seed and bulk layers may be thermally treated to increase the sizes of the W grains and reduce the resistance. Thus, the buried W may have a low resistance without degrading the threshold voltage V dispersion, even if the buried word line has a small dimension.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

1-6. (canceled)

7. A method of fabricating a semiconductor device, the method comprising:
forming a metal-containing stacked structure on a substrate, the metal-containing stacked structure including:
at least two seed layers, and
at least one metal layer disposed between the at least two seed layers and including a plurality of metal grains; and
etching a part of the metal-containing stacked structure to form a metal-containing wiring pattern that includes a remaining part of the metal-containing stacked structure.

8. The method as claimed in claim 7, wherein the at least two seed layers include boron (B).

9. The method as claimed in claim 7, wherein the plurality of metal grains includes at least one of W, Mo, Pt, or Rh.

10. The method as claimed in claim 21, wherein the annealing of the metal-containing wiring pattern is performed at a temperature of about 800 to about 1000° C.

11. The method as claimed in claim 21, wherein the annealing of the metal-containing wiring pattern is performed in a gas atmosphere of at least one of H₂, N₂, or Ar gases.

12. The method as claimed in claim 7, wherein substantially no portion of the at least one metal layer is removed until the etching of the part of the metal-containing stacked structure to form the metal-containing wiring pattern.

13. A method of fabricating a semiconductor device, the method comprising:
forming a trench in a semiconductor substrate;
forming a lower layer extending along an inner wall of the trench and defining a wiring space in the trench, the wiring space having a first width along a first direction;
forming a metal-containing stacked structure, the metal-containing stacked structure including:
at least two seed layers extending along the inner wall of the trench on the lower layer, and
at least one metal layer extending along the inner wall of the trench disposed between the at least two seed layers and having a plurality of metal grains, each of the plurality of metal grains having a particle diameter less than ½ of the first width in the first direction;
etching a part of the metal-containing stacked structure to form a metal-containing wiring pattern that includes a remaining part of the metal-containing stacked structure; and
increasing sizes of at least some of the plurality of metal grains in the metal-containing wiring pattern.

14. The method as claimed in claim 13, wherein the increasing of the sizes of at least some of the plurality of metal grains includes annealing the metal-containing wiring pattern.

15. The method as claimed in claim 13, wherein the increasing of the sizes of at least some of the plurality of metal grains is performed so that the metal-containing wiring pattern includes at least one metal grain having a particle diameter of about the first width along the first direction.

16. The method as claimed in claim 13, wherein the forming of the metal-containing stacked structure includes:
forming a first seed layer including boron (B) on the lower layer;
forming a first metal layer by using a chemical vapor deposition (CVD) process, such that the first metal layer extends along the inner wall of the trench on the first seed layer and includes a plurality of metal grains, each of the plurality of metal grains having a particle diameter that is less than ½ of the first width along the first direction; and
forming a second seed layer including boron (B) on the first metal layer.

17. The method as claimed in claim 13, wherein the forming of the metal-containing stacked structure includes:
supplying a boron-containing gas onto an exposed surface of the lower layer to form a seed layer; and
supplying a metal-containing gas onto the seed layer to form a metal layer.

18. The method as claimed in claim 17, wherein the metal-containing gas includes at least one of W, Mo, Pt, or Rh.

19. The method as claimed in claim 13, wherein the first width is a distance between two parts of the lower layer that are on opposite sides of the inner wall relative to a center of the trench.

20. The method as claimed in claim 13, wherein substantially no portion of the at least one metal layer is removed until the etching of the part of the metal-containing stacked structure to form the metal-containing wiring pattern.

21. The method as claimed in claim 7, further comprising annealing the metal-containing wiring pattern.
